(19) United States
(12) Patent Application Publication
(10) Pub. No.: US 2026/0059837 A1
(43) Pub. Date: Feb. 26, 2026

(54) SEMICONDUCTOR DEVICES HAVING INNER GATE RUNNERS WITH NON-ORTHOGONAL INNER SEGMENTS

(71) Applicant: Wolfspeed, Inc., Durham, NC (US)

(72) Inventor: Daniel Richter, Raleigh, NC (US)

(21) Appl. No.: 18/810,884

(22) Filed: Aug. 21, 2024

(51) Int. Cl. H01L 29/423

(52) U.S. Cl. CPC H10D 64/519; H10D 64/518

(57) ABSTRACT

A semiconductor device comprises a semiconductor layer structure, a gate pad on the semiconductor layer structure, and a metal gate runner on the semiconductor layer structure. The metal gate runner comprises an inner gate runner that comprises a first inner segment and a second inner segment that interconnect at a first oblique angle.

### FIELD

The present invention relates to semiconductor devices and, more particularly, to gate-controlled power semiconductor devices and to methods of fabricating such devices.

### BACKGROUND

The Metal Oxide Semiconductor Field Effect Transistor (“MOSFET”) is a well-known type of semiconductor transistor that may be used as a switch. A MOSFET is a three terminal device that has gate, drain and source terminals and a semiconductor body. The semiconductor body is referred to herein as a “semiconductor layer structure” and may include one or more semiconductor layers/regions. A source region and a drain region that each have a first conductivity type are formed in the semiconductor layer structure and are separated from each other by a channel region that has a second conductivity type. A gate electrode is disposed adjacent the channel region and separated from the channel region by a thin oxide layer. A MOSFET may be turned on or off by setting a bias voltage that is applied to the gate electrode to be above or below a threshold value. When a MOSFET is turned on (i.e., it is in its “on-state”), current is conducted through the channel region between the source and drain regions. When the bias voltage is reduced below the threshold level, the current ceases to conduct through the channel region.

An n-type MOSFET has source and drain regions that have n-type (electron) conductivity and a channel region that has p-type (hole) conductivity (i.e., an “n-p-n”design). An n-type MOSFET turns on when a gate bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type conductivity, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

Because the gate electrode of a MOSFET is insulated from the channel region by the gate oxide layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other circuit devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT.

In many applications, MOSFETs may need to carry large currents and/or be capable of blocking high voltages (e.g., hundreds or thousands of volts of electric potential). Such MOSFETs are often referred to as “power” MOSFETs. Power MOSFETs are often fabricated from wide band-gap semiconductor materials (herein, the term “wide band-gap semiconductor” encompasses any semiconductor having a band-gap of at least 1.4 eV). Power MOSFETs and other power semiconductor devices are often formed in silicon carbide (“SiC”), which has a number of advantageous characteristics including, for example, a high electric field breakdown strength, high thermal conductivity, high electron mobility, high melting point and high-saturated electron drift velocity.

Power semiconductor devices such as power MOSFETs can have a lateral structure or a vertical structure. In a device having a lateral structure, the terminals of the device (e.g., the drain, gate and source terminals for a power MOSFET) are on the same major surface (i.e., top or bottom) of a semiconductor layer structure. In contrast, in a device having a vertical structure, at least one terminal is provided on each major surface of the semiconductor layer structure (e.g., in a vertical MOSFET, the source and gate may be on the top surface of the semiconductor layer structure and the drain may be on the bottom surface of the semiconductor layer structure).

The semiconductor layer structure of a power semiconductor device includes an “active region” which acts as a main junction for blocking voltage during reverse bias (off-state) operation and for providing current flow during forward bias (on-state) operation. The power semiconductor device may also have an edge termination structure such as guard rings or a junction termination extension in a termination region of the semiconductor layer structure that is adjacent (and typically surrounding) the active region. The edge termination structure may, among other things, reduce electric field crowding effects that can occur at the outer edges of a power semiconductor device. Typically, multiple power semiconductor devices are formed in/on a common wafer, and each power semiconductor device will typically have its own edge termination structure. After the wafer is fully processed, the resultant structure may be diced to separate the individual edge-terminated power semiconductor devices. The singulated pieces of the wafer are often referred to as individual semiconductor die. Each power semiconductor device may have a unit cell structure in which the active region of each power semiconductor device includes a plurality of individual “unit cell” devices that are electrically connected in parallel and that together function as a single power semiconductor device.

Vertical gate-controlled power semiconductor devices can have a planar gate electrode design in which the gate electrodes are formed on top of the semiconductor layer structure or, alternatively, may have the gate electrodes formed within gate trenches in the semiconductor layer structure, which are typically referred to as gate trench devices. With the planar gate electrode design, the channel region of each unit cell transistor is horizontally disposed underneath the gate electrode. In contrast, in gate trench devices, the channels are typically vertically disposed adjacent sidewalls of the gate electrodes. Gate trench devices may provide enhanced performance, but typically require a more complicated manufacturing process. It will be appreciated that the metal gate runner designs of the semiconductor devices according to embodiments of the present invention that are discussed herein can be implemented in semiconductor devices having either planar or gate trench gate electrode designs.

FIGS. 1A and 1B illustrate two conventional gate structures for silicon carbide based power MOSFETs 10, 10′. In particular, FIGS. 1A-1B are schematic plan (i.e., top) views of power MOSFETs 10, 10′in which various of the upper metal and dielectric layers are omitted so that the gate pads, metal gate runners and gate electrodes are visible.

Referring to FIG. 1A, power MOSFET 10 includes an active region 12, a termination region 14 and a gate pad 20. The active region 12 is the region of power MOSFET 10 where the unit cell transistors are located that conduct current during on-state operation and block voltages during reverse bias (off-state) operation. The termination region 14 at least partially surrounds the active region 12 and is designed to reduce electric field crowding effects that can occur at the periphery of the active region 12. The termination region 14 may include one or more termination structures (not shown) such as guard rings or a junction termination extension. The gate pad 20 is a metal pad that acts as the gate terminal for the power MOSFET 10. The gate pad 20 may be formed on a field oxide layer and may partially overlap a respective polysilicon pattern (not visible in the figures). Power MOSFET 10 further includes a metal gate runner 30 that is electrically connected to the gate pad 20. A polysilicon gate runner (not shown) may be formed underneath the metal gate runner 30. The metal gate runner 30 includes an outer gate runner 32 that includes one or more outer segments 34 and an inner gate runner 36 that includes one or more inner segments 38. Herein, an outer gate runner refers to the portion of a metal gate runner that is on a periphery of the active region (e.g., positioned between the active region and the termination region) so that the active region is on only one side of each segment of the outer gate runner. Herein, an inner gate runner refers to portions of a metal gate runner that are within a region defined by an outer periphery or “footprint” of the active region. Thus, an inner gate runner refers to the portions of a metal gate runner that extend into the footprint of the active region so that the active region is on at least two sides of each segment of the inner gate runner. An inner gate runner is not part of the active region, but extends into the active region.

As shown in FIG. 1A, the outer gate runner 32 comprises a first outer segment 34-1 that extends horizontally (i.e., in the x-direction) to the left from an upper left side of the gate pad 20, a second outer segment 34-2 that extends vertically (i.e., in the y-direction) from a distal end of the first outer segment 34-1, a third outer segment 34-3 that extends horizontally (i.e., in the x-direction) to the right from an upper right side of the gate pad 20, and a fourth outer segment 34-4 that extends vertically (i.e., in the y-direction) from a distal end of the third outer segment 34-3. The inner gate runner 36 has a first inner segment 38-1 that extends vertically from a lower center portion of the gate pad 20. Power MOSFET 10 further includes a plurality of gate electrodes 40 that extend from the metal gate runner 30 and from the gate pad 20. The region where the gate electrodes 40 are provided corresponds to the active region 12. The gate electrodes 40 extend horizontally (i.e., in the x-direction) between the second outer segment 34-2 and the gate pad 20, between the second outer segment 34-2 and the first inner segment 38-1, between the fourth outer segment 34-4 and the gate pad 20, and between the fourth outer segment 34-4 and the first inner segment 38-1. When a gate signal is input to the gate pad 20, the gate signal flows to the metal gate runner 30, and from the metal gate runner 30 to the gate electrodes 40.

Power MOSFET 10′of FIG. 1B is nearly identical to power MOSFET 10 of FIG. 1A and hence like elements are identified using the same reference numerals and further description of these element is omitted. Power MOSFET 10′, however, has a different gate electrode design. In particular, power MOSFET 10′includes a first plurality of gate electrodes 40 that extend horizontally (i.e., in the x-direction) in the exact same manner as the gate electrodes 40 of power MOSFET 10, and also includes a second plurality of gate electrodes 40′ that extend vertically (i.e., in the y-direction) so that the gate electrodes 40′have a so-called “mesh” design where gate electrodes 40′extend in both the x-direction and the y-direction across the active region 12.

The gate electrodes 40, 40′in conventional silicon carbide based power MOSFETs are typically formed of polysilicon. Since the resistance of polysilicon is orders of magnitude greater than the resistance of a metal such as aluminum, the gate signals pass along the gate electrodes 40, 40′relatively slowly, which negatively impacts the switching speed of the power MOSFETs 10, 10′. The metal gate runner 30 provides a low-resistance path between the metal gate pad 20 and the gate electrodes 40, 40′, which improves the switching performance. The gate signals will almost entirely flow along the metal gate runner 30 (since metal is much less resistive than polysilicon) as the signal passes from the gate pad 20 to the gate electrodes 40, 40′. Note that herein the term “metal gate runner” encompasses both metal gate runners and metal silicide gate runners.

A wide variety of different metal gate runner designs are known in the art. FIGS. 2A-2J are schematic plan views of conventional power MOSFETs 10A-10J that show the locations of the metal gate pads 20A-20J and the metal gate runners 30B-30J on the semiconductor layer structures 16A-16J of each device while omitting all other upper dielectric and metallization layers, including the gate electrodes. As shown in FIGS. 2A-2J, the power MOSFETs 10A-10J may include no metal gate runner (FIG. 2A), a metal gate runner having only an outer gate runner 32B (FIG. 2B), metal gate runners having only inner gate runners 36C, 36F, 36I (FIGS. 2C, 2F, 2I), or metal gate runners having both outer gate runners 32D, 32E, 32G, 32H, 32J and inner gate runners 36D, 36E, 34G, 36H, 36J (FIGS. 2D, 2E, 2G, 2H, 2J).

### SUMMARY

Pursuant to some embodiments of the present invention, semiconductor devices are provided that comprise a semiconductor layer structure, a gate pad on the semiconductor layer structure, and a metal gate runner on the semiconductor layer structure that comprises an inner gate runner that comprises a first inner segment and a second inner segment that interconnect at a first oblique angle.

In some embodiments, the first inner segment extends from the gate pad along an axis that defines a second oblique angle with respect to a first major side of the gate pad. In some embodiments, the first inner segment connects the gate pad to the second inner segment. In some embodiments, the first inner segment extends from a corner of the gate pad. In some embodiments, the semiconductor device further comprises a plurality of source bond pads, and the first inner segment is positioned between a first of the source bond pads and a second of the source bond pads. In such embodiments, the semiconductor device comprises a metal oxide semiconductor field effect transistor that includes a plurality of unit cell transistors, and wherein a straight current path is provided between each unit cell transistor and at least one of source bond pads.

In some embodiments, the gate pad includes first and second major sides that extend along perpendicular axes and the first inner segment extends from a corner region of the gate pad at an angle of between 30° and 60° with respect to the first major side of the gate pad.

In some embodiments, the second inner segment extends in parallel to a first major side of the semiconductor layer structure, and the first inner segment extends from the second inner segment toward a corner region of the semiconductor layer structure.

In some embodiments, the inner gate runner further comprises a third inner segment, and the first inner segment, the second inner segment and the third inner segment each extend in different directions. In such embodiments, the inner gate runner may further comprise a fourth inner segment, and the first inner segment, the second inner segment, the third inner segment and the fourth inner segment each extend in different directions.

In some embodiments, the semiconductor layer structure comprises an active region, and wherein the metal gate runner further comprises an outer gate runner that extends around a portion of a periphery of the active region, where the outer gate runner comprises a first outer segment. In some embodiments, the inner first inner segment extends from the first outer segment. In some embodiments, the outer gate runner further comprises a second outer segment, and the first inner segment is interposed an on electrical path between the first outer segment and the second outer segment.

In some embodiments, the first inner segment extends from the gate pad along a first axis that defines a second oblique angle with respect to a first major side of the gate pad, and the inner gate runner further comprises a third inner segment that extends from the gate pad along a second axis that defines a third oblique angle with respect to the first major side of the gate pad.

Pursuant to further embodiments of the present invention, semiconductor devices are provided that comprise a semiconductor layer structure, a gate pad that comprises a plurality of major sides on the semiconductor layer structure, and a metal gate runner that comprises an inner gate runner that comprises a first inner segment that extends from the gate pad along an axis that defines a first oblique angle with respect to a first of the major sides of the gate pad.

In some embodiments, the inner gate runner further comprises a second inner segment that interconnects to the first inner segment at a second oblique angle. In some embodiments, the second inner segment extends in parallel to the first of the major sides of the gate pad. In some embodiments, the inner gate runner further comprises a third inner segment, and the first inner segment, the second inner segment and the third inner segment each extend in different directions. Moreover, the inner gate runner may further comprise a fourth inner segment, and the first inner segment, the second inner segment, the third inner segment and the fourth inner segment each extend in different directions.

In some embodiments, the first inner segment extends from a corner region of the gate pad.

In some embodiments, the semiconductor device further comprises a plurality of source bond pads, wherein the first inner segment is positioned between a first of the source bond pads and a second of the source bond pads. In some embodiments, the semiconductor device comprises a metal oxide semiconductor field effect transistor that includes a plurality of unit cell transistors, and wherein a straight current path is provided between each unit cell transistor and at least one of source bond pads.

In some embodiments, the first oblique angle is an angle of between 30° and 60°.

In some embodiments, the semiconductor layer structure comprises an active region, and wherein the metal gate runner further comprises an outer gate runner that extends around a portion of a periphery of the active region, where the outer gate runner comprises a first outer segment.

In some embodiments, the inner gate runner further comprises a second inner segment that extends from the gate pad along a second axis that defines a second oblique angle with respect to the first major side of the gate pad.

Pursuant to additional embodiments of the present invention, semiconductor devices are provided that comprise a semiconductor layer structure, a gate pad on the semiconductor layer structure, and a metal gate runner that comprises an inner gate runner that comprises a first inner segment that extends in a first direction, a second inner segment that extends in a second direction and a third inner segment that extends in a third direction, where the first, second and third directions are different.

In some embodiments, the inner gate runner further comprises a fourth inner segment, and the first inner segment, the second inner segment, the third inner segment and the fourth inner segment each extend in different directions.

In some embodiments, the first inner segment extends from the gate pad along an axis that defines a first oblique angle with respect to a first major side of the gate pad.

In some embodiments, the first inner segment extends from a corner region of the gate pad.

In some embodiments, the semiconductor device further comprises a plurality of source bond pads, wherein the first inner segment is positioned between a first of the source bond pads and a second of the source bond pads.

In some embodiments, the semiconductor device comprises a metal oxide semiconductor field effect transistor that includes a plurality of unit cell transistors, and wherein a straight current path is provided between each unit cell transistor and at least one of source bond pads.

In some embodiments, the first inner segment is electrically interposed between the gate pad and the second inner segment, and the second inner segment is electrically interposed between the first inner segment and the third inner segment, and the third inner segment interconnects to the second inner segment at a second oblique angle. In some embodiments, the third inner segment extends from the second inner segment toward a corner of the semiconductor layer structure.

In some embodiments, the gate pad includes first and second major sides that extend along perpendicular axes and the first inner segment extends from a corner region of the gate pad at an angle of between 30° and 60° with respect to the first major side of the gate pad.

In some embodiments, the semiconductor layer structure comprises an active region, and wherein the metal gate runner further comprises an outer gate runner that extends around a portion of a periphery of the active region, where the outer gate runner comprises a first outer segment. In some embodiments, the inner first inner segment extends from the first outer segment. In some embodiments, the outer gate runner further comprises a second outer segment, and the first inner segment is interposed an on electrical path between the first outer segment and the second outer segment.

In some embodiments, the first inner segment extends from the gate pad along a first axis that defines a first oblique angle with respect to a first major side of the gate pad, and the second inner segment extends from the gate pad along a second axis that defines a second oblique angle with respect to the first major side of the gate pad.

Pursuant to other embodiments of the present invention, semiconductor devices are provided that comprise a semiconductor layer structure that comprises a plurality of major sides, a gate pad on the semiconductor layer structure, and a metal gate runner that comprises an inner gate runner that comprises a first inner segment that extends along an axis that defines an oblique angle with respect to a first of the major sides of the semiconductor layer structure.

In some embodiments, the first inner segment directly connects to the gate pad.

In some embodiments, the gate pad includes first and second major sides that extend along perpendicular axes and the first inner segment extends from a corner region of the gate pad at an angle of between 30° and 60° with respect to the first major side of the gate pad.

In some embodiments, the inner gate runner further comprises a second inner segment, and second inner segment is electrically interposed between the gate pad and the first inner segment.

In some embodiments, the inner gate runner further comprises a second inner segment that extends in parallel to the first of the major sides of the semiconductor layer structure, and the first inner segment extends from the second inner segment toward a corner of the semiconductor layer structure.

In some embodiments, the inner gate runner further comprises a second inner segment and a third inner segment, and wherein the first inner segment, the second inner segment and the third inner segment each extend in different directions. In some embodiments, the inner gate runner further comprises a fourth inner segment, and the first inner segment, the second inner segment, the third inner segment and the fourth inner segment each extend in different directions. In some embodiments, the metal gate runner further comprises an outer gate runner that comprises a first outer segment. In some embodiments, the inner first inner segment extends from the first outer segment. In some embodiments, the outer gate runner further comprises a second outer segment, and the first inner segment is interposed an on electrical path between the first outer segment and the second outer segment.

Pursuant to still other embodiments of the present invention, semiconductor devices are provided that comprise a semiconductor layer structure, a gate pad on the semiconductor layer structure, and a metal gate runner that comprises an inner gate runner, where the inner gate runner has a spine and rib configuration that comprises a first rib that comprises a first inner segment and a second inner segment that interconnect at a first oblique angle.

In some embodiments, the inner gate runner further comprises at least a second rib and a third rib that are each closer to the gate pad than the first rib. In some embodiments, the inner gate runner further comprises a fourth rib that comprises a third inner segment and a fourth inner segment that interconnect to define a second oblique angle. In some embodiments, portions of the first rib and the fourth rib extend along a common axis.

In some embodiments, the second inner segment extends from the first inner segment toward a corner region of the semiconductor layer structure

Pursuant to yet additional embodiments of the present invention, semiconductor devices are provided that comprise a semiconductor layer structure, a gate pad on the semiconductor layer structure, and a metal gate runner that comprises an inner gate runner that comprises a first inner segment that is curved.

In some embodiments, the semiconductor layer structure has four major sides, and a distance between the first inner segment and a first of the major sides continuously increases with increasing distance from a second of the major sides.

In some embodiments, the first inner segment directly connects to the gate pad. In some embodiments, the inner gate runner comprises a second inner segment that is electrically interposed between the gate pad and the first inner segment.

Pursuant to still further embodiments of the present invention, semiconductor devices are provided that comprise a semiconductor layer structure, a gate pad on the semiconductor layer structure, and a metal gate runner that comprises an inner gate runner. These semiconductor devices are configured so that on-state source current distribution has a variation of between 0.5% and 10%.

In some embodiments, these semiconductor devices may be configured so that on-state source current distribution has a variation of less than 8% or a variation of less than 5%.

In some embodiments, a source metallization is on the semiconductor layer structure, and no more than three source bond pads are provided on the source metallization. In some embodiments, the semiconductor layer structure defines a rectangle in plan view that has four quadrants, and wherein the gate pad is in a first of the four quadrants and the three source bond pads are in the respective second through four quadrants.

### BRIEF DESCRIPTION OF DRAWINGS

FIGS. 1A and 1B are schematic plan views of two conventional power MOSFETs that illustrate the gate structure of each MOSFET.

FIGS. 2A-2J are schematic plan views of a variety of conventional power MOSFETs that show the locations of the gate pad and the metal gate runners.

FIG. 3A is a schematic top view of a silicon carbide power MOSFET according to certain embodiments of the present invention.

FIG. 3B is a schematic top view of the silicon carbide power MOSFET of FIG. 3A with various of the upper metal and dielectric layers removed.

FIG. 3C is a schematic top view of the portion of the silicon carbide power MOSFET of FIG. 3B shown in the box labelled A in FIG. 3B.

FIG. 3D is a schematic cross-sectional view taken along the line 3D-3D of FIG. 3C with portions of the upper metallization and dielectric layers of the power MOSFET added for context.

FIG. 3E is a schematic cross-sectional view taken next to the box labeled A in FIG. 3B.

FIG. 4A is a schematic plan view of the conventional power MOSFET of FIG. 2J that illustrates how conventional gate runner designs may result in non-uniform on-state current distribution.

FIG. 4B is a schematic plan view of the power MOSFET of FIGS. 3A-3E that illustrates how the gate runner designs according to embodiments of the present invention may provide more uniform on-state current distribution.

FIGS. 5A-5C are schematic top views of power MOSFETS according to further embodiments of the present invention.

FIG. 6A is a schematic top view illustrating the metal gate runner design of another conventional power MOSFET.

FIG. 6B is a schematic top view of the conventional power MOSFET of FIG. 6A illustrating the time it takes each portion of the active region to reach a set gate voltage during device turn-on.

FIG. 7A is a schematic top view of a power MOSFET according to still further embodiments of the present invention.

FIG. 7B is a schematic top view of the power MOSFET of FIG. 7A illustrating the time it takes each portion of the active region to reach a set gate voltage during device turn-on.

FIG. 8 is a schematic top view of a power MOSFET according to yet additional embodiments of the present invention.

FIG. 9 is a schematic cross-sectional view of a gate trench power semiconductor device according to embodiments of the present invention.

Two-part reference numerals that include a hyphen are used herein in some instances to distinguish between different ones of multiple like elements. The full two-part reference numeral may be used in the description to refer to individual of these elements, while the first part of the reference numeral may be used to refer to the elements collectively.

### DETAILED DESCRIPTION

The present invention stems, in part, from a realization that the addition of metal gate runners to a power semiconductor device involves inherent performance tradeoffs. As discussed above, adding metal gate runners to a power semiconductor device advantageously increases the switching speed of the device (and thus reduces switching losses). However, the addition of metal gate runners reduces the size of the active region, which increases the on-state resistance of the device, resulting in increased conduction losses. Moreover, the addition of metal gate runners having inner gate runners may also negatively impact the ability to have as many source bond wires as may be desired, which also can negatively impact the performance of the device. In addition, in some instances, expanding the metal gate runner can degrade the on-state source current distribution of a power semiconductor device. Thus, there are a variety of tradeoffs that must be considered in designing the metal gate runner for a power semiconductor device.

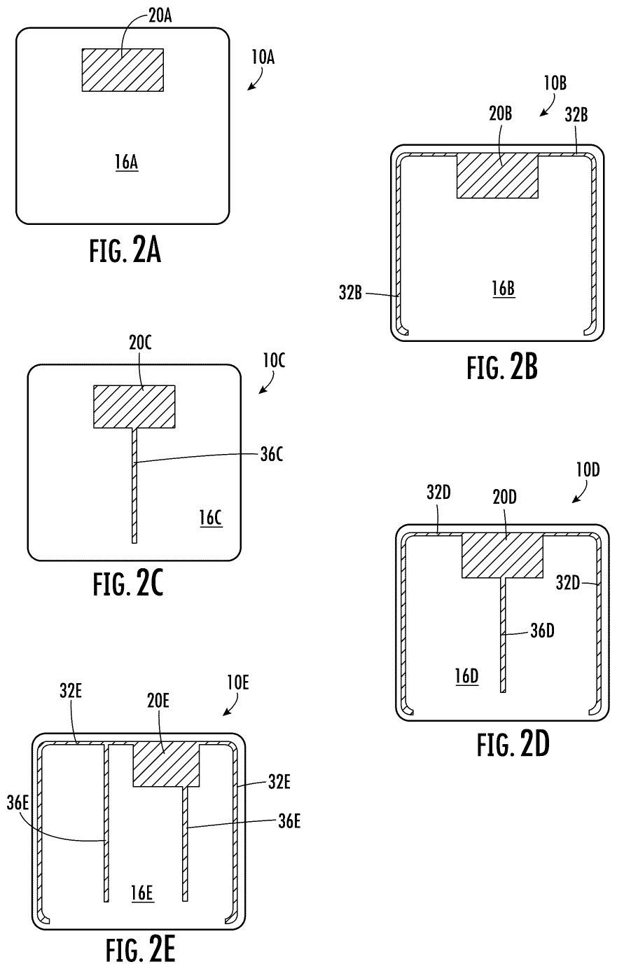

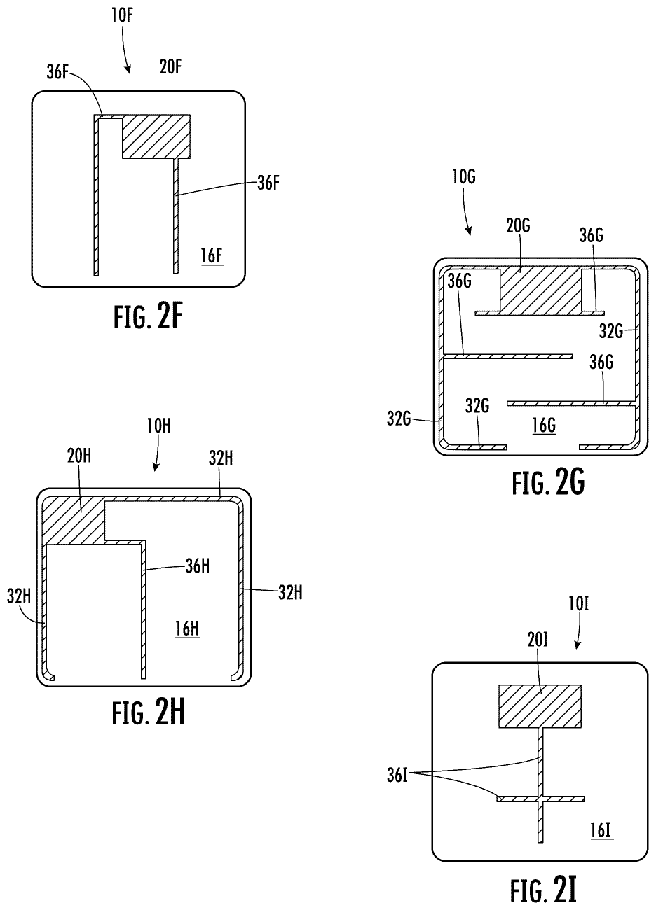

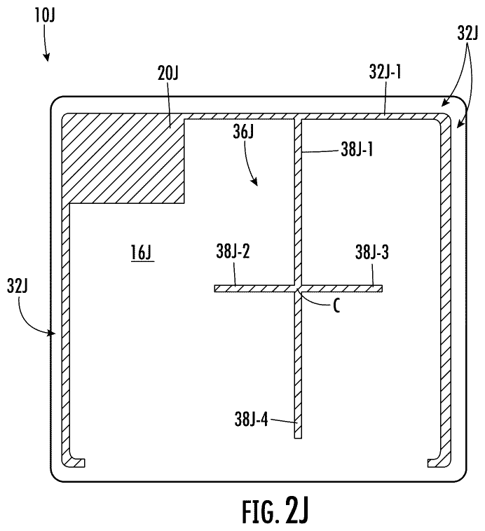

A semiconductor die refers to singulated piece of a processed semiconductor wafer and thus includes a semiconductor layer structure as well as various metal and dielectric layers formed thereon to provide an operable device. As shown in FIGS. 2A-2J, conventional power semiconductor devices typically include one or more power semiconductor die that have a rectangular shape (and hence 90° corners) as the individual semiconductor die are cut from a larger wafer using a saw or laser cutting techniques. While the semiconductor die itself typically has sharp corners, the termination structures, gate runners and/or source metallization typically have rounded corners, as the rounding helps reduce peak electric field concentrations in the corners of the die. Thus, each semiconductor die in FIGS. 2A-2J has a rectangular shape, and various structures within the die (e.g., the gate runner, the termination structures, etc.) may have major sides that are connected by sharp or rounded corners. The term “corner region” is used herein to refer to corners that are formed by two sides that intersect at a right angle as well as rounded corners, beveled corners and the like. Herein, a “major” side of a semiconductor die (or other structure such as a semiconductor layer structure or gate pad) refers to a side that is at least 10% of a perimeter of the die (or other structure) when viewed from above (i.e., in plan view). The conventional metal gate runner designs in the power semiconductor die of FIGS. 2A-2J have metal gate runners that, excepts at the corners of the die, only have horizontally (x-direction) or vertically (y-direction) extending inner and outer segments. Such horizontally and vertically extending segments of a metal gate runner may be referred to herein as “orthogonal” segments since they define axes that intersect various sides of the rectangular semiconductor die at angles of 90°. Notably, the inner gate runners in all of the power semiconductor devices of FIGS. 2A-2J have inner gate runners that only include orthogonal inner segments.

Power semiconductor devices that only include inner gate runners that have “orthogonal” inner segments may not provide an optimum tradeoff between, for example, switching speed and on-state resistance performance. In particular, by replacing horizontal and/or vertical inner segments of a conventional inner gate runner with “non-orthogonal” inner segments that define oblique angles with the major sides of the semiconductor die it is possible to reduce the total length of the inner gate runner (resulting in a greater percentage of the semiconductor die being available to serve as the active region) with little or no impact on the performance of the device. The use of such non-orthogonal or “angled” inner segments may also improve the on-state current distribution in the power semiconductor device by, for example, eliminating inner segments that cause current crowding in the source metallization and/or by allowing source bond wires to be positioned more centrally in the region of the device that receive current from the respective source bond wires. In addition, the use of non-orthogonal inner segments may also allow the gate signal to be more uniformly distributed throughout the device so that the unit cells turn on and off more uniformly when the device switches between on-state and off-state operation. This may improve the switching speed of the device, and may also improve reliability.

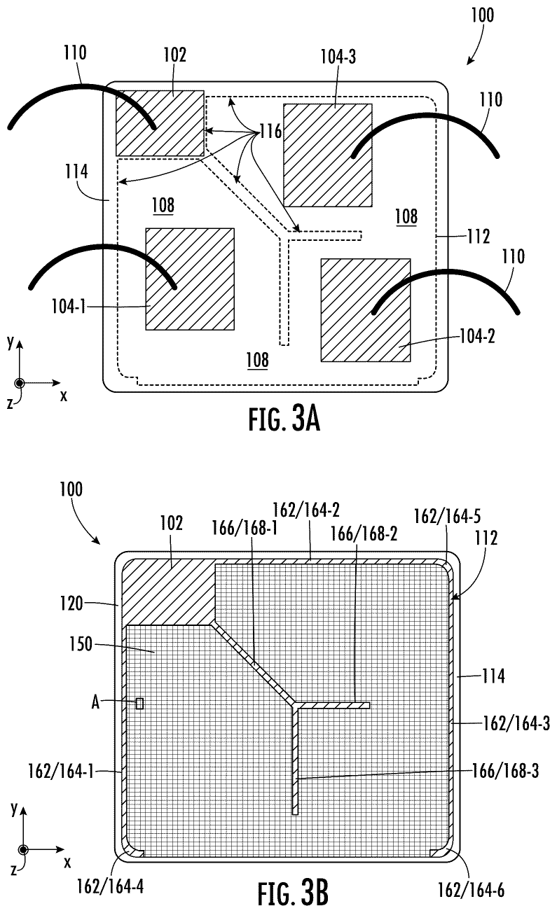

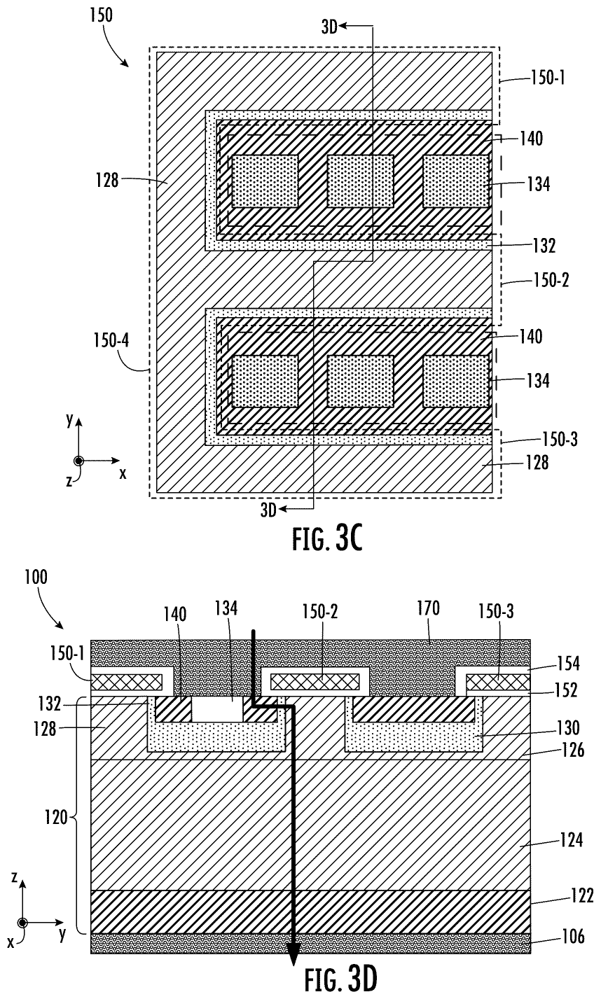

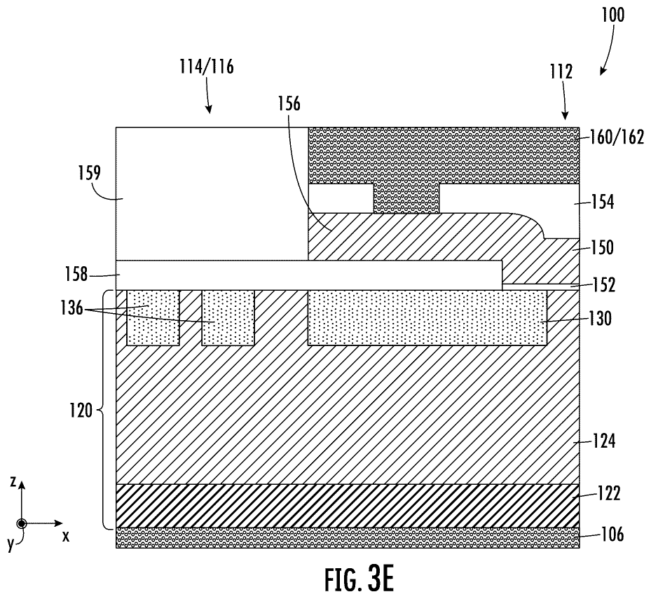

Example embodiments of power semiconductor devices according to embodiments of the present invention will now be described with reference to FIGS. 3A-9. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations. Additionally, while the example embodiments focus on MOSFET implementations, it will be appreciated that the same techniques may be used in other gate trench power semiconductor devices such as insulated gate bipolar transistors (IGBTs), gate-controlled thyristors and the like.

FIG. 3A is a schematic top view of a vertical silicon carbide power MOSFET 100 according to certain embodiments of the present invention. FIG. 3B is a schematic plan view of the power MOSFET 100 with various upper metal and dielectric layers thereof omitted. FIG. 3C is a schematic top view of the portion of the power MOSFET 100 of FIG. 3B shown in the box labelled A in FIG. 3B. FIG. 3D is a schematic cross-sectional view of about two unit cells of the power MOSFET 100 that is taken along line 3D-3D of FIG. 3C. FIG. 3E is a schematic cross-sectional view taken adjacent the box labelled A in FIG. 3B. It will be appreciated that the thicknesses of various of the layers and regions in FIGS. 3A-3E are not necessarily drawn to scale. The same is true with respect to the other figures included in this application.

The power MOSFET 100 includes a semiconductor layer structure 120 (see FIGS. 3C-3E) that comprises one or more semiconductor substrates and/or layers. At least one (and typically all) of the semiconductor layers in the semiconductor layer structure 120 may be silicon carbide layers. Various semiconductor, metal and/or dielectric layers are formed on either side of the semiconductor layer structure 120 and/or embedded in the semiconductor layer structure 120.

As shown in FIG. 3A, the top-side metal layers include a gate pad 102 and a plurality of source pads 104 that are formed on the upper side of the semiconductor layer structure 120. A total of three source pads 104-1 through 104-3 are shown, but other numbers of source pads 104 may be used. A metal drain pad 106 (see FIGS. 3D-3E) is provided on the bottom side of the semiconductor layer structure 120. The gate pad 102, the source pads 104 and the drain pad 106 form the respective gate, source and drain terminals of power MOSFET 100. The gate and source pads 102, 104 may each be formed of one or more metals, including, for example, a metal such as aluminum that bond wires can be readily attached to via conventional techniques such as ultrasonic heavy wire bonding. Thus, the gate pad 102 and/or the source pads 104 may be also be referred to herein as “bond” pads in some cases. The drain pad 106 may likewise be a metal pad. A protective layer 108 such as a polyimide layer may cover the entire upper surface of power MOSFET 100 except for the gate and source pads 102, 104.

The source pads 104 typically comprise portions of a source metallization layer 170 (described below) that are exposed through openings in the protective layer 108. The source metallization layer 170 electrically connects certain regions of the semiconductor layer structure 120 to the source pads 104. The source metallization layer 170 may generally overlie or correspond to an “active region” 112 of the power MOSFET 100 where the unit cell transistors are located. The dashed lines in FIG. 3A illustrate the location of the active region 112 since it is underneath the metal pads 102, 104 and the protective layer 108. A termination region 114 extends at least part of the way around the periphery of power MOSFET 100 to at least partly surrounds the active region 112. The termination region 114 may comprise one or more termination structures (not shown in FIG. 3A) such as guard rings or a junction termination extension region. Bond wires 110 are shown in FIG. 3A that may be used to connect the gate pad 102 and the source pads 104 to external circuits or the like. The drain pad 106 on the bottom side of power MOSFET 100 may be connected to an external circuit through, for example, an underlying submount (not shown). The power MOSFET 100 may include additional inactive regions 116 such as the region where the gate pad 102 and a metal gate runner 160 (discussed below) are formed.

FIG. 3B is another plan view of power MOSFET 100 with the source pads 104, the polyimide layer 108, the source metallization layer 170, and various dielectric layers omitted to show the gate electrodes 150 that are formed on the upper surface of the semiconductor layer structure 120 and a metal gate runner 160 that electrically connects the gate pad 102 to the gate electrodes 150. As shown in FIG. 3B, a metal gate runner 160 electrically connects the gate pad 102 to the gate electrodes 150, which extend throughout the active region 112. The gate electrodes 150 have a mesh structure where both horizontally-extending and vertically-extending gate electrodes 150 are provided. The metal gate runner 160 includes an outer metal runner 162 and an inner metal runner 166. As discussed above, the outer metal runner 162 is the portion of the metal gate runner 160 that extends along an outer periphery of the active region 112 and the inner metal runner 166 is the portion of the metal gate runner 160 that is within the footprint defined by the outer periphery of the active region 112.

The outer metal runner 162 comprises multiple “outer segments” 164. The inner gate runner 166 comprises a plurality of “inner segments” 168. Herein, a “segment” refers to a distinct portion of the outer gate runner 162 or the inner gate runner 166 such as a linear segment or a curved or angled section that connects to other distinct segments. Power MOSFET 100 includes a total of six outer segments 164, namely three long straight segments 164-1 through 164-3 and three short segments 164-4 through 164-6 that are at the corners of the active region 112. Power MOSFET 100 includes a total of three inner segments 166, namely a first inner segment 168-1 that extends from a lower right corner of the gate pad 120 toward the center of the die at an angle of about 45° with respect to the upper and lower sides of the die and/or gate pad 102, a second inner segment 168-2 that extends horizontally (i.e., in the x-direction) to the right from the distal end of the first inner segment 168-1, and a third inner segment 168-3 that extends vertically downward (i.e., in the y-direction) from the distal end of the first inner segment 168-1. The inner gate runner 166 is the portion of a metal gate runner 160 that extends into the footprint of the active region 112 so that the active region 112 is on at least two sides of each inner segment 168 of the inner gate runner 166.

Referring again to FIG. 3A, the termination region 114 comprises part of an “inactive” region 116 of power MOSFET 100, which refers to the region of the device that does not include active unit cells. The inactive region 116 further includes the regions of the device where metal gate structures are provided, which are the regions where the gate pad 102 and the metal gate runner 160 are formed.

A field oxide layer 158 (FIG. 3E) is provided on the semiconductor layer structure 120 in the inactive region 116 of the MOSFET 100. The field oxide layer 158 may be a relatively thick oxide layer (e.g., ten to twenty times thicker than the gate oxide layers that are discussed below). A polysilicon pattern is provided on the field oxide layer 158 and on selected portions of the active region 112. The portions of the polysilicon pattern that are formed on the field oxide layer 158 may comprise, for example, a polysilicon runner 156 (FIG. 3E) that is positioned underneath the metal gate runner 160 and a polysilicon region that is formed underneath the outer edge of the gate pad 102. The portions of the polysilicon pattern that are provided in the active region 112 form the gate electrodes 150 of the power MOSFET 100.

The active region 112 typically encompasses well over 50% of the area of the semiconductor die, and often well over 80% of the die area, where the “die area” refers to the area of the die when viewed from above (i.e., in plan view).

FIG. 3C is a schematic top view of the upper surface of the semiconductor layer structure 120 of the portion of the silicon carbide power MOSFET 100 of FIG. 3B that is shown in the box labelled A in FIG. 3B. The dotted region in FIG. 3C illustrate the locations of the gate electrodes 150. The locations where three horizontally-extending gate electrodes 150-1 through 150-3 and one vertically extending gate electrode 150-4 will be formed on the semiconductor layer structure 120 are shown in FIG. 3C. It will be appreciated that the horizontally and vertically extending gate electrodes 150 merge into each other so that the gate electrodes 150 may comprise a continuous monolithic gate electrode. The dashed regions in FIG. 3C illustrate the locations where the source metallization layer 170 directly contacts the upper surface of the semiconductor layer structure 120.

FIG. 3D is a cross-sectional view taken along line 3D-3D of FIG. 3C. The cross-section of FIG. 3D shows one full unit cell of the MOSFET 100 and portions of two adjacent unit cells. It should be noted that the cross-section of FIG. 3D is not taken along a straight line but instead includes a “jog” to show cross-sections of two different regions of power MOSFET 100.

Referring to FIGS. 3C-3D, the power MOSFET 100 includes an n-type silicon carbide semiconductor substrate 122 such as, for example, a single crystal 4H silicon carbide semiconductor substrate that is heavily-doped with n-type impurities. The n-type doping concentration of the substrate 122 may be, for example, between 1×10¹⁸ atoms/cm³ and 1×10²¹ atoms/cm³, although other doping concentrations may be used. Herein, the “doping concentration” of a semiconductor material refers to the number of dopant atoms that cause the semiconductor material to have a certain conductivity type (i.e., either n-type or p-type) that are present within a cubic centimeter of semiconductor material as measured using standard measurement techniques such as Secondary Ion Mass Spectrometry (“SIMS”). The doping concentration of a layer or region may be relatively constant or may vary (e.g., be graded with depth), and the doping concentration refers to the peak doping concentration of the layer or region. For an n-type semiconductor material, references to the doping concentration refer to the concentration of n-type dopants and for a p-type semiconductor material, references to the doping concentration refer to the concentration of p-type dopants. The substrate 122 may be any appropriate thickness (e.g., between 100 and 500 microns thick), and it will be appreciated that the substrate 122 will typically be much thicker than shown. The thickness of various other layers of power MOSFET 100 likewise may not be shown to scale in order to allow other portions of the devices to be enlarged in the figures. The substrate 122 may be partially or fully removed in some embodiments.

A lightly-doped n-type silicon carbide drift region 124 is provided on the upper surface of the substrate 122. The n-type silicon carbide drift region 124 may be formed by, for example, epitaxial growth on the silicon carbide substrate 122. The n-type silicon carbide drift region 124 may have, for example, a doping concentration of 1×10¹⁴ to 5×10¹⁶ dopants/cm³. The doping concentration may vary with the voltage blocking rating of the device, with devices having higher voltage blocking ratings typically having lower doping concentrations in the drift region 124. For example, a MOSFET 100 having a voltage blocking rating of 10 kV or more might have a drift region n-type doping concentration of between 1×10¹⁴ to 5×10¹⁴ dopants/cm³, whereas a MOSFET 100 having a voltage blocking rating of 500-1200 V might have a drift region n-type doping concentration of between 1×10¹⁶ to 5×10¹⁶ dopants/cm³. The n-type silicon carbide drift region 124 may be a thick region, having a vertical height above the substrate 122 of, for example, 3-50 microns. An upper portion of the n-type silicon carbide drift region 124 may be more heavily doped than the remainder of the drift region 124 to provide a current spreading layer 126 in an upper portion of the drift region 124. The doping concentration of this current spreading layer 126 may be, for example, about 1.5 to 4.0 times higher than the doping concentration of the remainder of the drift region 124. The current spreading layer 126 may be formed during the epitaxial growth process. Herein, the current spreading layer 126, if provided, is considered to be part of the drift layer 124 and hence will not be discussed separately.

A plurality of p-type well regions 130 (which may also be referred to herein as “p-wells”) are formed on upper portions of the n-type drift region 124. While not shown in the figures, a large p-well 130 may also be formed underneath the portion of the field oxide layer 158 that underlies the gate pad 102, and p-wells 130 may also be formed underneath the polysilicon runner 156. The p-wells 130 may all be interconnected in some embodiments. The p-wells 130 may have a doping concentration of, for example, between 5×10¹⁵ cm⁻³ and 5×10¹⁹ cm⁻³ and, more typically, between 5×10¹⁶ cm⁻³ and 5×10¹⁹ cm⁻³. The p-wells 130 may be formed via ion implantation. As known to those skilled in the art, ions such as n-type or p-type dopants may be implanted in a semiconductor layer or region by ionizing the desired ion species and accelerating the ions at a predetermined kinetic energy as an ion beam towards the surface of a semiconductor layer in an ion implantation target chamber. Based on the predetermined kinetic energy, the desired ion species may penetrate into the semiconductor layer. The ions will implant at different depths into the semiconductor layer so that the predetermined kinetic energy will provide an implant “profile” with varying ion concentrations as a function of depth. The dopants may comprise, for example, Al⁺or N⁺ions, although any appropriate dopant ions may be used. In some embodiments, the implantation may be performed at different temperatures such as, for example, temperatures of 75° C. or more. It will be appreciated that the p-wells 130 often have a doping concentration that varies with depth. The p-wells 130 in the active region include channel regions 132 (discussed in more detail below) formed therein. These channel regions 132 may be less heavily doped than other portions of the p-well 130.

A plurality of n-type JFET regions 128 are defined in the upper portion of the drift region 124 between adjacent p-wells 130 underneath the gate electrodes 150. Each JFET region 128 may comprise a region of n-type material and may or may not be more heavily doped n-type than the lower portion of the drift region 124.

A plurality of heavily-doped n-type silicon carbide source regions 140 are formed in upper portions of the p-wells 130. The source region 140 may have a doping concentration of, for example, between 5×10¹⁸ cm⁻³ and 5×10²¹ cm⁻³. In addition, heavily-doped p-type silicon carbide well contact regions 134 are also formed on upper portions of the p-wells 130. As shown, the well contact regions 134 may appear as a plurality of “islands” in each source region 140 when the MOSFET 100 is viewed in plan view. It will be appreciated, however, that in other embodiments the well contact regions 134 may connect to each other along the x-direction so that a single elongated well contact region 134 is provided between each pair of adjacent gate electrodes 150. Other configurations for the well contact and source regions 134, 140 are known in the art and may be used. The well contact regions 134 and the source regions 140 may each be formed via ion implantation. The substrate 122, the drift region 124 (including any current spreading layer 126 and the JFET regions 128), the p-wells 130 (including the channel regions 132 and the well contact regions 134) and the source regions 140 together comprise the semiconductor layer structure 120 of MOSFET 100.

As shown in FIG. 3D, a plurality of gate dielectric layers 152 are formed on the upper surface of the semiconductor layer structure 120. The gate dielectric layers 152 may or may not be connected to each other along the periphery of the MOSFET 100. The gate dielectric layers 152 may comprise, for example, silicon oxide layers, although other insulating materials may be used. The gate electrodes 150 are formed on the respective gate dielectric layers 152. The gate electrodes 150 may comprise, for example, a conductive material such as polysilicon, a silicide or a metal. As discussed above, the gate electrodes 150 may be part of a larger polysilicon pattern. One or more intermetal dielectric layers 154 may cover the respective gate electrodes 150. The intermetal dielectric layers 154 may comprise, for example, silicon oxide.

The upper surface of the semiconductor layer structure 120 is exposed in between adjacent intermetal dielectric patterns 154. The source regions 140 and the p-type well contact regions 134 are thus exposed in between adjacent intermetal dielectric patterns 154. A source metallization 170 is formed over the upper surface of the MOSFET 100 so that the source metallization 170 makes electrical contact to the n-type source regions 140 and the p-type well contact regions 134 while being electrically insulated from the gate electrodes 150 by the intermetal dielectric patterns 154. The source metallization 170 may comprise, for example, an ohmic contact layer such as a silicide layer that directly contacts the semiconductor layer structure 120 and a bulk metal layer (e.g., an aluminum layer) that is on the ohmic contact layer opposite the semiconductor layer structure 120. The source metallization 170 may include additional layers such as barrier layers, adhesion layers, grain stop layers and the like. A drain contact 106 is formed on the lower surface of the substrate 122. The drain contact 106 may comprise, for example, the same or similar materials to the source metallization 170, and may form an ohmic contact to the silicon carbide substrate 122.

FIG. 3E is a cross-sectional view that illustrates the termination region 114 of MOSFET 100 and the interconnection between the outer gate runner 162 and the gate electrodes 150. As shown in FIG. 3E, the termination region 114 includes a termination structure in the form of a pair of guard rings 136. Each guard ring 136 may be implemented as a moderately-doped or highly-doped p-type region in the upper portion of the semiconductor layer structure 120. Each guard ring 136 may extend completely around the periphery of the active region 112. The left edge of the active region 112 is shown in FIG. 3E.

As is also shown in FIG. 3E, the field oxide layer 158 is formed on the upper surface of the semiconductor layer structure 120 and the polysilicon runner 156 is formed on the field oxide layer 158. An additional dielectric layer 159 is formed on the field oxide layer 158 above the guard rings 136. A p-well 130 is formed underneath the field oxide layer 158 and vertically overlaps the field oxide layer 158 and the polysilicon runner 156. As used herein, two elements of a semiconductor device are considered to “vertically overlap” if an axis that is perpendicular to the major surfaces of a semiconductor layer structure of the semiconductor device intersects both elements. The intermetal dielectric layer 154 extends onto the upper surface of the polysilicon runner 156. A trench is formed in the intermetal dielectric layer 154 and the outer gate runner 162 is formed on the intermetal dielectric layer 154 and in the trench in the intermetal dielectric layer 154 to electrically connect the outer gate runner 162 to the polysilicon runner 156. The outer gate runner 162 vertically overlaps the polysilicon runner 156. The polysilicon runner 156 merges into the ends of the gate electrodes 150 as shown.

As discussed above with reference to FIG. 3B, power MOSFET 100 has a mesh gate electrode design. When a gate signal is applied to the gate pad 102, it may pass directly to the gate electrodes 150 that connect directly to the gate pad 102, and the gate signal will also flow into and along the metal gate runner 160. The amount of gate signal that flows along each possible path will be a function of the resistance of the path. The gate signal will ultimately flow along the length of all of the gate electrodes 150, but since the metal gate runner 160 provides a path having a far lower resistance, the gate signal will largely be distributed throughout the active region 112 through the metal gate runner 160 and will then flow from the metal gate runner 160 along each individual gate electrode 150.

The metal gate runner design shown in FIG. 3B may ensure that the gate signal does not have to flow through a long stretch of polysilicon, thereby providing enhanced switching speed. For example, the farthest distance that any point on a gate electrode 150 is from the metal gate runner 160 is less than one third the length of the sides of power MOSFET 100. In addition, the amount of die area that is devoted to the metal gate runner 160 is relatively low, so that the power MOSFET 100 will also exhibit relatively low on-state resistance values.

Power MOSFET 100 of FIGS. 3A-3E may be viewed as an improved version of power MOSFET 10J of FIG. 2J. Referring again to FIG. 2J, the conventional power MOSFET 10J has an inner gate runner 36J that comprises a first inner segment 38J-1 that extends vertically downwardly from a first segment 34J-1 of the outer gate runner 32J to a central point C, a second inner segment 38J-2 that extends horizontally to the left from the central point C, a third inner segment 38J-3 that extends horizontally to the right from the central point C, and a fourth inner segment 38J-4 that extends vertically downwardly from the central point C. Power MOSFET 100 of FIGS. 3A-3E may be identical to power MOSFET 10J except that the inner gate runner 166 of power MOSFET 100 omits the first and second inner segments 38J-1, 38J-2 of the inner gate runner 36J of power MOSFET 10I and replaces them with a non-orthogonal first inner segment 168-1 (note that the third and fourth inner segments 38J-3, 38J-4 of power MOSFET 10J are renumbered as the second and third inner segments 168-2, 168-3 of the inner gate runner 166 in power MOSFET 100).

As can be seen by comparing FIGS. 2J and 3B, the combined length of the first and second inner segments 38J-1, 38J-2 of power MOSFET 10J is about 50% longer than the length of inner segment 168-1 of power MOSFET 100. Thus, power MOSFET 100 has a shorter inner gate runner 168 than power MOSFET 10J, and hence a larger active region 112, since less of the semiconductor layer structure is devoted to the metal gate runner 160. Moreover, the metal gate runner design of power MOSFET 100 distributes that gate signal throughout the device almost as efficiently as the metal gate runner design of power MOSFET 10J. The reduction in active region area consumed by the metal gate runner 160 of power MOSFET 100 may be worth any slight degradation in the ability of power MOSFET 100 to efficiently distribute the gate signal throughout the active region as compared to power MOSFET 10J.

Referring again to FIG. 3B, it can be seen that pursuant to some embodiments of the present invention, semiconductor devices such as MOSFET 100 are provided that comprise a semiconductor layer structure 120. A gate pad 102 and a metal gate runner 160 are provided on the semiconductor layer structure 120. The metal gate runner 160 comprises an inner gate runner 166 that in turn comprises at least a first inner segment 168-1.

In some embodiments, the inner gate runner 166 may further comprise a second inner segment 168-2, and the first inner segment 168-1 and the second inner segment 168-2 may interconnect at an oblique angle. In example embodiments, the oblique angle may be between 30° and 60°.

In other embodiments, the first inner segment 168-1 may alternatively or additionally extend from the gate pad 102 along an axis that defines an oblique angle with respect to a first major side of the gate pad 102.

In still other embodiments, the inner gate runner 166 may further comprise both a second inner segment 168-2 and a third inner segment 168-3, and the first inner segment 168-1, the second inner segment 168-2 and the third inner segment 168-3 may each extend in different directions. Herein, a “direction” refers to a direction in the x-y-z coordinate system shown in the figures. Thus, two parallel segments extend in the same direction. For example, in FIG. 3B, the second inner segment 168-2 and the second outer segment 164-2 extend in the same direction (namely in the x-direction). As can be seen in FIG. 3B, the first through third inner segments 168-1 through 168-3 each extend in different directions.

In still further embodiments, the first inner segment 168-1 may alternatively or additionally extend along an axis that defines an oblique angle with respect to a first major side of the semiconductor device 100.

In some or all of the above embodiments, the first inner segment 168-1 may extend from the gate pad 102 along an axis that defines an oblique angle with respect to a first major side of the gate pad 102. In some embodiments, the first inner segment 168-1 may extend from a corner of the gate pad 102. In some embodiments, the gate pad 102 includes first and second major sides that extend along perpendicular axes and the first inner segment 168-1 extends from a corner region of the gate pad 102 at an angle of between 30° and 60° with respect to the first major side of the gate pad 102. In some embodiments, the first inner segment 168-1 may connect the gate pad 102 to the second inner segment 168-1.

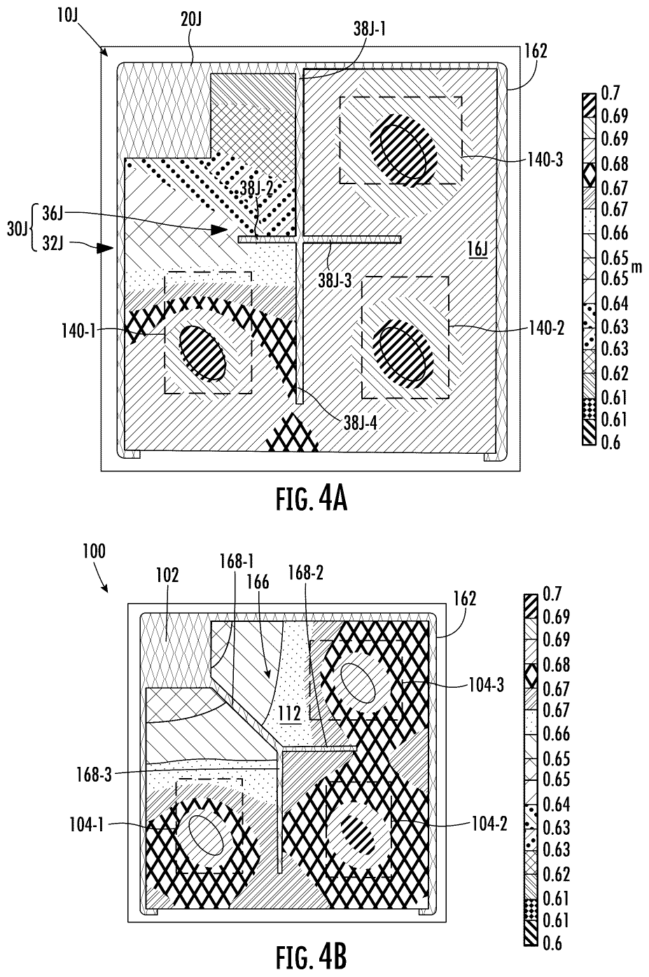

The use of inner gate runners that have non-orthogonal inner segments may also improve the on-state performance of power MOSFET 100. This can be seen with reference to FIGS. 4A and 4B. In particular, FIG. 4A is a plan view of the power MOSFET 10J of FIG. 2J that illustrates the simulated surface electric potential of the source metallization during on-state operation. Since the power MOSFET is designed to operate in its linear region (as opposed to at saturation), the simulated surface electric potential of the source metallization directly corresponds to the on-state source-to-drain current. As shown in FIG. 4A, the inner gate runner 36J of power MOSFET 10J includes a first inner segment 38I-J that extends downwardly from the outer gate runner 32, a second inner segment 32I-2 that extends to the left from the distal end of the first inner segment 38I-1, a third inner segment 32I-3 that extends to the right from the distal end of the first inner segment 38I-1, and a fourth inner segment 38I-4 that extends downwardly from a distal end of the first inner segment 38I-1. The dashed squares in FIG. 4A represent the locations of three source pads 140-1 through 140-3 of power MOSFET 10J that may have source bond wires coupled thereto.

In FIG. 4A, the shading in the active region 16J denotes the surface electric potential of the source metallization during on-state operation of power MOSFET 10J. As noted above, FIG. 4A also shows the on-state current density since the surface electric potential is linearly related to the on-state current density. As can be seen in FIG. 4A, the surface electric potential is the highest directly underneath the source pads 140, as current flowing into the semiconductor layer structure 16J in these regions of the power MOSFET 10J encounter the least amount of resistance in the source metallization. The surface electric potential then slowly decreases with increasing distance from the source pads 140, at least in the upper right, the lower right and the lower left quadrants of power MOSFET 10J. However, in the upper left quadrant of the device, it can be seen that the surface electric potential in the source metallization may be significantly reduced, particularly in the region between the gate pad 20J and the first inner segment 38J-1 of the inner gate runner 36J. This reduction occurs for two reasons. First, since the inner gate runner 36J is formed within gaps in the source metallization, the source current cannot flow across the inner gate runner 36J. As such, the source current must flow from the lower left source pad 140-1 through a relatively narrow gap between the distal end of the second inner segment 38J-2 and the left edge of the semiconductor die to flow into the upper left quadrant of the device. This narrowed gap acts to increase the resistance and therefore reduces the current flow into the upper left quadrant of the device. Second, the physical current path from the closest source pad 140-1 to the upper portion of the upper left quadrant of the device is longer than the current path from a source pad 140 to any other region of the device, and this increased current path has increased resistance, further reducing current flow to the upper left quadrant of the device.

Ideally, power semiconductor devices such as power MOSFET 100 have uniform on-state current distribution for at least two reasons. First, generally speaking, the larger the current level in any region of the device, the more heating that occurs, and excessive heating can degrade device performance and/or cause reliability issues. Thus, if the current distribution is uniform, then heating of the device may be more uniform and the negative effects of excessive heating may be reduced. Second, the current and voltage ratings for a power semiconductor device are often set to ensure that the device meets certain reliability specifications. Since failure of any unit cell may damage or destroy a power semiconductor device, the current and voltage ratings may be set based on the unit cells that carry the highest on-state currents, as these may be the cells that are most likely to fail. If the current distribution is made more uniform, then the device may, for a given current rating, have improved reliability performance, since increased on-state current may flow through unit cells that had lower on-state current levels in less efficient designs.

FIG. 4B is a plan view of the power MOSFET 100 of FIGS. 3A-3E that illustrates the simulated surface electric potential of the source metallization during on-state operation, which (pursuant to Ohm's Law) directly corresponds to the source-to-drain current density in the source metallization 170. The dashed squares in FIG. 4B represent the locations of the source pads 104-1 through 104-3. As shown in FIG. 4B, the first inner segment 168-1 of the inner gate runner 166 is positioned between the first source bond pad 104-1 and the third source bond pad 104-3. As can also be seen in FIG. 4B, the on-state surface electric potential is much more uniform in power MOSFET 100 than it is in power MOSFET 10J, since the use of a non-orthogonal inner segment 168-1 eliminates the current constriction effects that were present in power MOSFET 10J, and also reduces the maximum distance from a point in the active region 112 to the closest source pad 104. The power MOSFET 100 is configured so that a straight current path is provided between every unit cell transistor in the semiconductor layer structure 120 and at least one of source bond pads 104-1 through 104-3. Power MOSFET 100 may exhibit improved on-state performance as compared to power MOSFET 10J for these reasons.

Simulations show that the maximum voltage drop on the source pad is 11.3% for the device of FIG. 4A, whereas the maximum voltage drop on the source pad is reduced to 5.3% for the device of FIG. 4B. Moreover, the size of the active region is 20.34 mm² in the device of FIG. 4A, whereas the size of the active region in the device of FIG. 4B is 20.51 mm². In other words, the device of FIG. 4B has a larger active region (which reduces the on-state resistance, which allows for higher current handling due to less heat generation) and also exhibits reduced voltage drop on the source pad. In addition, the uniformity of the surface electric potential (which is a measure of the current density uniformity) in the device of FIG. 4B is 97.59%, whereas the device of FIG. 4A exhibits a lower level of uniformity (96.79%). Thus, the device of FIG. 4B exhibits improved performance over the device of FIG. 4A in several different ways without any other negative effects.

One way to characterize the uniformity of the on-state surface electric potential (and hence the uniformity of the on-state source current distribution) is as the difference between the maximum and minimum on-state surface electric potentials in the source metallization 170 divided by the maximum surface electric potential. As shown in FIG. 4A, the maximum on-state surface electric potential for power MOSFET 10J is about 0.7, while the minimum on-state surface electric potential is about 0.61. Thus, the uniformity of the on-state surface electric potential for power MOSFET 10J is (0.7 −0.61)/0.7=12.9%. As shown in FIG. 4B, the maximum on-state surface electric potential for power MOSFET 100 is about 0.68, while the minimum on-state surface electric potential is about 0.65. Thus, the uniformity of the on-state surface electric potential for power MOSFET 100 is (0.68−0.65)/0.68=4.4%. Thus, the on-state surface electric potential (and hence the on-state source current distribution) for power MOSFET 100 is almost three times better than the on-state surface electric potential (and hence the on-state source current distribution) for power MOSFET 10J.

Thus, as shown in FIGS. 3A-3B and 4B, pursuant to some embodiments of the present invention, semiconductor devices such as power MOSFET 100 are provided that comprise a semiconductor layer structure 120 that has an active region 112 therein, a gate pad 102 on the semiconductor layer structure 120, and a metal gate runner 160 that comprises an inner gate runner 166. Moreover, the semiconductor device 100 is configured so that on-state source current distribution has a variation of less than 10%. In other embodiments, the semiconductor device may be configured so that on-state source current distribution has a variation of less than 8% or even less than 5%. The on-state source current distribution may be at least 0.5% in the above embodiments. The semiconductor device 100 may have a source metallization 170 on the semiconductor layer structure 120, and no more than three source bond pads 104 may be provided on the source metallization 170. The semiconductor layer structure 120 may define a rectangle in plan view (i.e., in the view of FIG. 4B) that has four quadrants, and where the gate pad 102 is in a first of the four quadrants and the three source bond pads 104-1 through 104-3 are in the respective second through four quadrants.

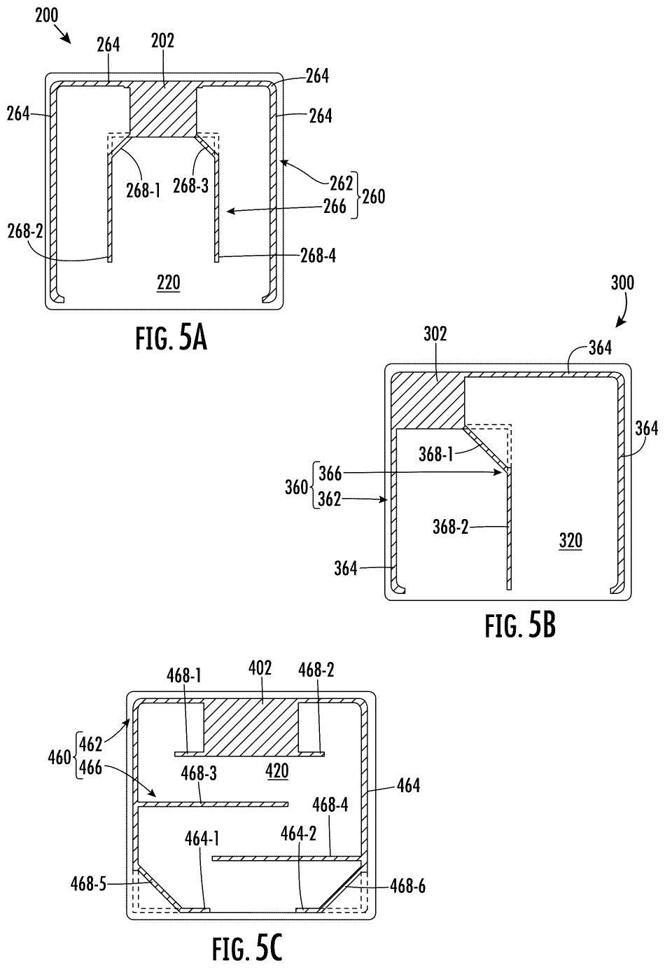

FIGS. 5A-5C are schematic top views of power MOSFETs according to further embodiments of the present invention that include metal gate runners having inner gate runners that have one or more non-orthogonal inner segments. In FIGS. 5A-5C the upper polyimide layer, the gate electrodes, the top-side dielectric layers, and the source metallization are omitted so that only the upper surface of the semiconductor layer structure and the gate metallization (i.e., gate pad and metal gate runner) are shown to simplify the figures. Additionally, in FIGS. 5A-5C the dotted lines illustrate the location of additional gate inner segments that would be included in more conventional counterparts to the power MOSFETs of FIGS. 5A-5C.

Referring first to FIG. 5A, a power MOSFET 200 is illustrated that includes a gate pad 202 and a metal gate runner 260 that includes an outer gate runner 262 and an inner gate runner 266. The outer gate runner 262 extends around the periphery of the semiconductor layer structure 220 on three sides thereof. The outer gate runner 262 includes three long straight outer segments 264 as well as four corner segments 264. The inner gate runner 266 includes a first non-orthogonal inner segment 268-1 that extends from a lower left corner of the gate pad 202, a second segment 268-2 that extends vertically from the distal end of the first inner segment 268-1, a third non-orthogonal inner segment 268-3 that extends from a lower right corner of the gate pad 202, and a fourth segment 268-4 that extends vertically from the distal end of the third inner segment 268-3.

A more conventional version of the power MOSFET 200 of FIG. 5A would not include the first and third non-orthogonal inner segments 268-1, 268-3 and instead would include two additional inner segments that extend from the lower left and right corners of the gate pad 202, and the second and fourth inner segments 268-2, 268-4 would extend farther upwardly to connect to these respective segments, as shown by the dotted boxes in FIG. 5A. As can be seen, the inner gate runner in the conventional design is disadvantageously longer than the inner gate runner 266 of power MOSFET 200. In addition, in the conventional design, the unit cells in the upper corners of the semiconductor layer structure have metal gate runner segments on three or even four sides thereof, and hence the delay to these unit cells (i.e., the time that an applied gate signal takes to reach these unit cells) may, on average, be significantly less than the average delay to the unit cells in the remainder of the device. In contrast, in power MOSFET 200, the time that a gate signal takes to reach each unit cell is made more uniform.

Referring to FIG. 5B, a power MOSFET 300 is illustrated that includes a gate pad 302 and a metal gate runner 360 that includes an outer gate runner 362 and an inner gate runner 366. The outer gate runner 362 extends around the periphery of the semiconductor layer structure 320 on three sides thereof. The outer gate runner 362 may be identical to outer gate runner 262 so further description thereof will be omitted. The inner gate runner 366 includes a first non-orthogonal inner segment 368-1 that extends downwardly and to the right from a lower right corner of the gate pad 302, and a second segment 368-2 that extends vertically from the distal end of the first inner segment 368-1.

As shown by the dotted lines in FIG. 5B, in a more conventional design, the inner gate runner would comprise a first inner segment that extends horizontally to the right from the lower corner of the gate pad and the inner segment 368-2 would be extended to connect to the distal end of this first inner segment. However, as with the conventional counterpart to power MOSFET 200 of FIG. 5A, such a design increases the total length of the inner gate runner and results in less even distribution of the gate signal as compared to power MOSFET 300.

Referring to FIG. 5C, a power MOSFET 400 is illustrated that includes a gate pad 402 and a metal gate runner 460 that includes an outer gate runner 462 and an inner gate runner 466. The outer gate runner 462 extends around the periphery of the semiconductor layer structure 420 on three sides thereof, and also includes two short outer segments 464 on the fourth side of the semiconductor layer structure 420. The inner gate runner 466 includes first and second inner segments 468-1, 468-2 that extend from the respective lower corners of the gate pad 402, a third inner segment 468-3 that extends from the outer segment on the left side of the semiconductor layer structure 420, a fourth inner segment 468-4 that extends from the outer segment on the right side of the semiconductor layer structure 420, and fifth and sixth non-orthogonal inner segments 468-5, 468-6 that extend from distal ends of the respective outer segments 464 on the left and rights sides of the semiconductor layer structure 420. The fifth and sixth non-orthogonal inner segments 468-5, 468-6 connect the short outer segments 464 on the lower side of the semiconductor layer structure 420 to the outer segments 464 on the respective left and right sides of the semiconductor layer structure 420. Power MOSFET 400 illustrates that an inner segment of an inner gate runner can extend at an oblique angle from an outer segment of an outer gate runner and/or that an inner segment of an inner gate runner can connect two outer segments of an outer gate runner.

As is further shown in FIG. 5C, in a more conventional design, the fifth and sixth non-orthogonal inner segments 468-5, 468-6 would be omitted and the outer segments 464 on the left, right and lower sides of the semiconductor layer structure 420 would be extended as shown to interconnect. Such a design increases the total length of the metal gate runner, reducing the size of the active region and also does not distribute the gate signal as efficiently as the metal gate runner 460 of power MOSFET 400.

Thus, FIGS. 5A-5C illustrate additional gate metal runner designs that have non-orthogonal inner segments that may provide improved performance as compared to conventional designs.

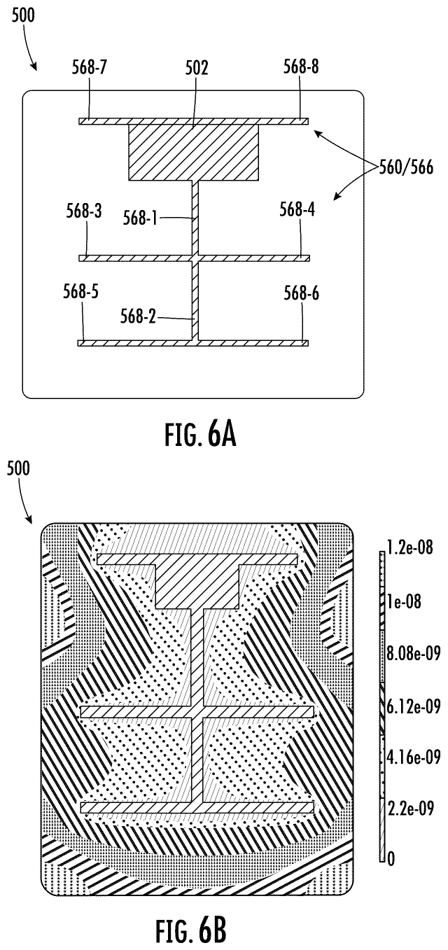

FIG. 6A is a schematic top view illustrating the metal gate runner design of another conventional power MOSFET 500. In FIG. 6A the upper polyimide layer, the gate electrodes, the top-side dielectric layers, and the source metallization are again omitted so that only the upper surface of the semiconductor layer structure and the gate metallization are shown.

As shown in FIG. 6A, power MOSFET 500 has a metal gate runner 560 that has an inner gate runner 566 but no outer gate runner. The inner gate runner 566 comprises first and second vertically-extending inner segments 568-1, 568-2, four horizontally-extending inner segments 568-3 through 568-6 that extend in pairs from the distal ends of the respective first and second vertically-extending inner segments 568-1, 568-2 and seventh and eighth inner segments 568-7, 568-8 that extend horizontally from upper corners of the gate pad 502. The first and second vertically-extending inner segments 568-1, 568-2 together form a “spine” and the four horizontally-extending inner segments 568-3 through 568-6 form respective “ribs” that extend from the spine. The lengths of the ribs may be adjusted to meet a specific gate resistance target, and the distance between the end of each rib and an adjacent edge of the active region may impact current crowding, so the length of the ribs may also be adjusted based on current crowding considerations.

FIG. 6B is a schematic top view of the conventional power MOSFET 500 of FIG. 6A illustrating the time it takes each portion of the active region to reach a set gate voltage during device turn-on. In FIG. 6B, the shading indicates the time (in fractions of a second) that it takes each portion of the active region to reach the set gate voltage. FIG. 6B thus can be viewed as showing how long it takes the gate current to reach a pre-specified level in the different unit cells of the device. As shown in FIG. 6B, the unit cell transistors that are near the inner gate runner 566 reach the set gate voltage relatively quickly However, there are regions along the sides of the die and along the bottom of the die where the delay is larger. This may be undesirable for at least two reasons. First, the increased delay reduces the switching speed of power MOSFET 500 since the added delay means that it takes the MOSFET 500 longer to turn on or off. Second, because the unit cells turn on and off at different times, some unit cells may experience higher electric field levels than others. This may reduce the reliability of the device

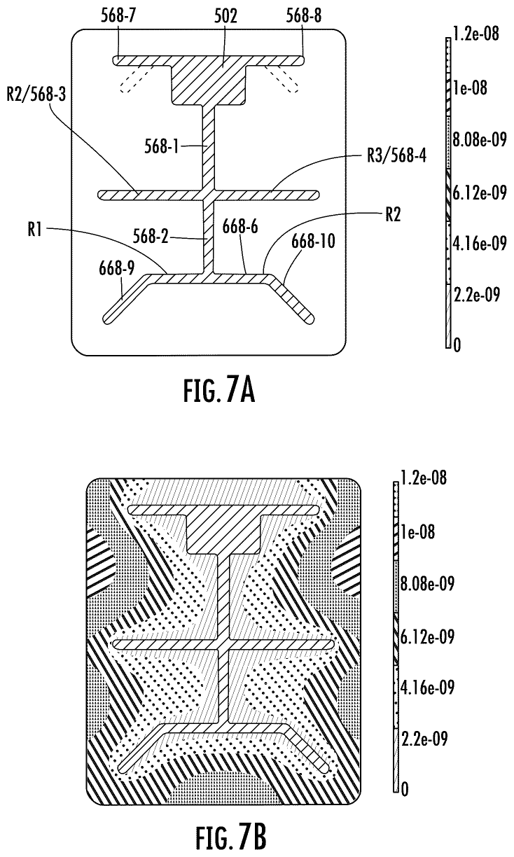

FIG. 7A is a schematic top view of a power MOSFET 600 according to further embodiments of the present invention that has an inner gate runner 666. As shown, MOSFET 600 is very similar to power MOSFET 500 of FIG. 6A, but in power MOSFET 600 the fifth and sixth inner segments 568-5, 568-6 of power MOSFET 500 are replaced with shorter fifth and sixth inner segments 668-5, 668-6, and non-orthogonal inner segments 668-9, 668-10 are added that extend from the distal ends of inner segments 668-5, 668-6, respectively. Non-orthogonal inner segments 668-9, 668-10 extend toward the respective lower corners of the semiconductor die.

FIG. 7B is a schematic top view of the power MOSFET of FIG. 7A illustrating the time it takes each portion of the active region to reach a set gate voltage during device turn-on, where the same set gate voltage was used in the simulations that were performed to generate FIGS. 6B and 7B. In FIG. 7B, the shading again indicates the time that it takes each portion of the active region to reach the set gate voltage. Since non-orthogonal inner segments 668-9, 668-10 extend toward the respective lower corners of the semiconductor die, they reduce the time that it takes the unit cells in the lower corners of the device to reach the set gate voltage as compared to the time required in the similar power MOSFET of FIG. 6B. As can be seen by comparing FIGS. 6B and 7B, this results in more uniform distribution of the gate current throughout the device as a function of time. As shown by the dotted lines in FIGS. 7A-7B, in other embodiments the seventh and eighth inner segments 568-7, 568-8 that extend horizontally from upper corners of the gate pad 502 may similarly be shortened, and two additional non-orthogonal inner segments 668 may be added that extend from the distal ends of the respective shortened seventh and eighth inner segments 568-7, 568-8. This further design change may reduce the time that it takes the gate current to reach the regions along the upper side edges of the die in FIG. 7B that have larger delays.

Generally speaking, it is advantageous to have the unit cell transistors turn on (and off) in response to a gate signal with a high degree of uniformity. In other words, ideally all of the unit cell transistors would turn on and off at exactly the same time. As shown in FIGS. 6B and 7B, this behavior does not occur in practice because the gate signal must travel from the gate pad 102 to the unit cell transistors throughout the active region 112. Moreover, the speed at which the gate signal spreads throughout the device depends on the material it is travelling through, with the gate signal travelling more quickly through the inner gate runner 666 than it does through the polysilicon gate fingers. Consequently, the uniformity of the gate signal distribution time may be improved if the distance between any particular unit cell and the metal gate runner is made smaller.

One way of quantifying the uniformity of the gate signal distribution time may be viewed as the difference between the maximum and minimum times that it takes the gate signal to reach any particular unit cell divided by the maximum times that it takes the gate signal to reach a unit cell. As shown in FIG. 6B, the maximum time that it takes the gate signal to reach a unit cell for power MOSFET 10J is about 12×10⁻⁹ seconds, while the minimum time that it takes the gate signal to reach a unit cell for power MOSFET 10J is about 1×10⁻⁹ seconds. Thus, the uniformity of the gate signal distribution time for power MOSFET 10J is (12×10⁻⁹−1×10⁻⁹)/12×10⁻⁹=92%. As shown in FIG. 7B, the maximum time that it takes the gate signal to reach a unit cell for power MOSFET 100 is about 9×10⁻⁹ seconds, while the minimum time that it takes the gate signal to reach a unit cell for power MOSFET 100 is about 1×10⁻⁹ seconds. Thus, the uniformity of the gate signal distribution time for power MOSFET 100 is (9×10⁻⁹−1×10⁻⁹)/ 9×10⁻⁹=89%. This improvement is achieved using the same amount of metal gate runner area in the two power MOSFETS 10J, 100.

Still referring to FIGS. 7A-7B, it can be seen that pursuant to some embodiments of the present invention, semiconductor devices such as power MOSFET 600 are provided that comprise a semiconductor layer structure 120. A gate pad 502 and a metal gate runner 660 that comprises an inner gate runner 666 are provided on the semiconductor layer structure 120. The inner gate runner 666 has a spine and rib configuration that comprises a first rib R1 that comprises a first inner segment 668-5 and a second inner segment 668-9 that interconnect to define an oblique angle. The inner gate runner 666 further comprises at least a second rib R2 and a third rib R3 that are each closer to the gate pad 502 than the first rib R1. The inner gate runner 666 may additionally comprise a fourth rib R4 that comprises a third inner segment 668-6 and a fourth inner segment 668-10 that interconnect to define another oblique angle. Portions of the first rib R1 and the fourth rib R4 may extend along a common axis. The second inner segment 668-9 may extend from the first inner segment 668-5 toward a corner region of the semiconductor layer structure 120.

As the above discussion makes clear, a number of tradeoffs are involved in the design of a metal gate runner for a power semiconductor device. One consideration is the amount of die area devoted to the metal gate runner. The more die area devoted to the gate runner the more quickly (and typically, the more uniformly as well) the gate current can be distributed throughout the active area and the lower the gate resistance. Both of these effects may be advantageous. However, as the greater the percentage of the die area that is devoted to the metal gate runner, the smaller the percentage of the die that comprises the active region. As the size of the active region is reduced, so are the current carrying capabilities of the device.

The provision of inner gate segments may be very effective at decreasing the time it takes the gate signal to reach unit cells in the middle of a die. Moreover, inner gate segments may be more effective than outer gate segments at reducing the time it takes to distribute the gate current throughout the device, as inner gate segments connect to polysilicon gate electrodes on both sides thereof. However, inner gate segments can also force the on-state source current to travel along longer current paths, which is undesirable. Adding more source bond pads can sometimes eliminate long source current paths, but adding additional source bond wires increase manufacturing complexity, and in many cases there may not be sufficient room on the die for additional source bond pads.

As demonstrated above, by using non-orthogonal inner gate segments it may be possible to achieve improved tradeoffs between the amount of die area that is devoted the metal gate runner, the gate current distribution time and uniformity, as well as the uniformity of the source current distribution.

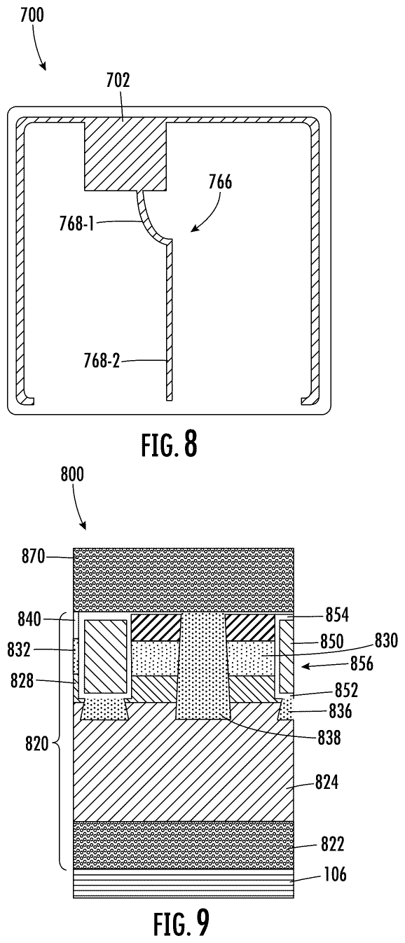

FIG. 8 is a schematic top view of a power MOSFET 700 according to yet additional embodiments of the present invention. The previously discussed power MOSFETs all have inner gate runners that have straight inner segments. It will be appreciated, however, that embodiments of the present invention are not limited thereto. For example, the inner gate runner 766 of power MOSFET 700 includes a first inner segment 768-1 that extends downwardly from the gate pad 702 and curves to connect to the base of the second inner segment 768-2. In some cases, curved inner segments may provide further improvements in performance in terms of, for example, reducing the amount of die area that is devoted to the metal gate runner.

FIG. 9 is a schematic cross-sectional view of a gate trench power MOSFET 800 according to embodiments of the present invention. The plan views of FIGS. 3A and 3B accurately represent power MOSFET 800 as well as power MOSFET 100, and the cross-sectional view shown in FIG. 9 is taken along a vertical cut through box A of FIG. 3B.

As shown in FIG. 9, power MOSFET 800 includes a semiconductor layer structure 820. The semiconductor layer structure 820 includes a substrate 822 and a drift region 824 that may be identical to substrate 122 and a drift region 124 of power MOSFET 100. The semiconductor layer structure 820 of power MOSFET 800 further comprises a JFET region 828, a plurality of p-wells 830 and a plurality of source regions 840 which may be identical to the similarly numbered elements (i.e., elements with a reference number that is seven hundred less than the reference numbers in FIG. 9) of power MOSFET 100 except that the shapes of these regions are different in power MOSFET 500.

As can be seen by comparing FIGS. 3D and 9, power MOSFET 800 primarily differs from power MOSFET 100 in that the gate dielectric layers 852 and gate electrodes 850 of power MOSFET 800 are formed within trenches 856 in the semiconductor layer structure 820 instead of being formed on a planar upper surface of a semiconductor layer structure 120 as is the case with power MOSFET 100. As a result, the channels 832 are formed in the portions of the p-wells 830 that form the sidewalls of the trenches 856. Thus, in power MOSFET 800 the channels 832 are vertical channels whereas in power MOSFET 100 the channel 132 are horizontal channels. As is further shown in FIG. 9, p-type trench shields 836 may be formed underneath each gate trench 856 and/or p-type support shields 838 may be formed in between each pair of gate trenches 856.

Power MOSFET 800 is thus very similar to power MOSFET 100, with the primary difference being that the gate electrodes 850 are formed within trenches 856 in the semiconductor layer structure 820. As such, power MOSFET 800 may look identical to power MOSFET 100 in the view of FIG. 3B. It will be appreciated that the metal gate runner designs according to embodiments of the present invention may be used in power MOSFETs having trench gate electrodes. In fact, any of the power MOSFETs discussed above with respect to FIGS. 3A-8 may have either a planar gate electrode design or a trench gate electrode design.

As discussed above, the switching performance of a power MOSFET may be improved if the maximum distance between the metal gate runner of the MOSFET and any portion of a gate electrode is reduced, as this ensures that the maximum time required to distribute a gate signal to all portions of the active region is minimized. Generally speaking, the more the average distance from the metal gate runner to all positions along all of the gate electrodes is reduced the better the switching performance of the power MOSFET. At the same time, however, it is desirable to keep the amount of die area used to implement the metal gate runner small, as the more area devoted to the metal gate runner the smaller the active region, which negatively impacts the on-state resistance performance of the power MOSFET.

The power semiconductor devices according to embodiments of the present invention include metal gate runners that have inner gate runners that include “non-orthogonal” inner segments that extend along axes that form acute and/or obtuse angles with major sides of the semiconductor die, the semiconductor layer structure or the gate pad. These non-orthogonal inner segments may extend from the gate pad, from other inner segments or from outer segments of an outer gate runner of the metal gate runner.

As described above, the use of these “angled” inner segments may allow a reduction in the amount of semiconductor die area required to implement the metal gate runner with little or no reduction in the efficiency with which the gate signal is distributed throughout the active region.

Inner gate runners may be preferred over outer gate runners because outer gate runners may be more prone to delamination. In addition, inner gate runners of a metal gate runner may be more effective at reducing the amount of die area used to implement the metal gate runner than outer gate runners. However, one problem with using inner gate runners having a larger number of inner segments is that the source metallization/source pads and the gate pads/metal gate runners are typically all formed in a single process using a single metal layer, and hence the source pads often cannot vertically overlap the metal gate runner. The use of angled inner segments may create larger regions where the source bond pads may be formed, which may allow for greater use of the more efficient inner segments.

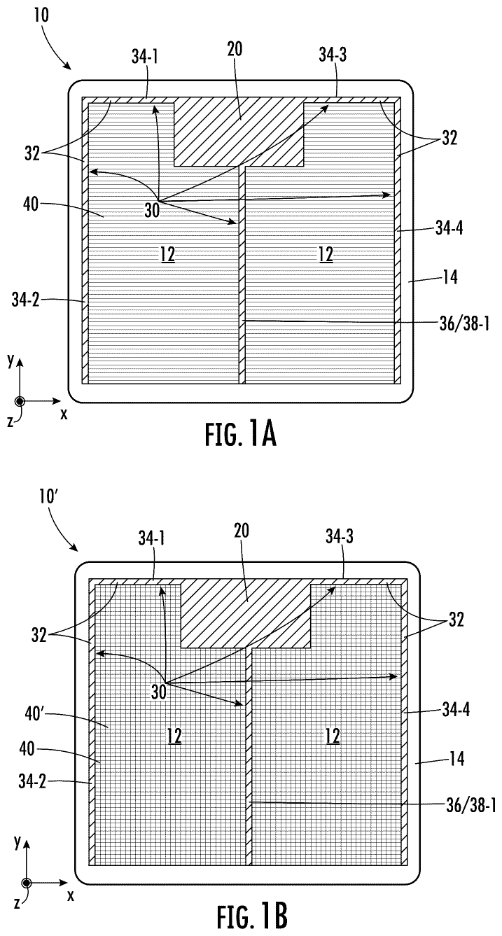

While the above discussion focuses on power MOSFETs that have mesh gate designs in which the gate electrodes extend in both the horizontal and vertical directions when the power MOSFET is viewed in plan view, it will be appreciated that embodiments of the present invention are not limited thereto. In particular, the techniques disclosed herein may be used in power MOSFETs having gate electrodes that only extend in the horizontal direction (as shown in the power MOSFET of FIG. 1A) and in power MOSFETs having gate electrodes that only extend in the vertical direction (as shown in the power MOSFET of FIG. 1B). In such power MOSFETs, the metal gate runner designs may need to be modified slightly (e.g., the lengths of one or more inner or outer segments may need to be lengthened) so that every gate electrode connects to the metal gate runner, since the individual gate electrodes are not interconnected through a gate electrode mesh. It will also be appreciated that the techniques disclosed herein are equally applicable to power MOSFETs having so-called cell designs where hexagonal or other-shaped unit cells are provided.

While the above discussion focuses on n-channel MOSFETs, it will be appreciated that pursuant to further embodiments of the present invention, the polarity of each of the semiconductor layers in each device could be reversed so as to provide corresponding p-channel MOSFETs. Likewise, while the embodiments of the present invention discussed above are MOSFETs, it will be appreciated that the techniques disclosed herein may also be used to form insulated gate bipolar junction transistors (IGBTs) that include a MOSFET according to embodiments of the present invention, or other gate controlled power semiconductor devices.

Herein, embodiments of the present invention are described with respect to cross-sectional diagrams that show one or two unit cells of a power switching devices. It will be appreciated that actual implementations will typically include a much larger number of unit cells. However, it will also be appreciated that the present invention is not limited to such devices, and that the claims appended hereto also cover MOSFETs and other power switching devices that comprise, for example, a single unit cell. Moreover, while the present disclosure focuses on silicon carbide devices, it will be appreciated that embodiments of the present invention may also have applicability to devices formed using other wide band-gap semiconductors such as, for example, gallium nitride, zinc selenide or any other II-VI or III-V wide band-gap compound semiconductors.

The invention has been described above with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the invention are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A semiconductor device, comprising:
a semiconductor layer structure;
a gate pad on the semiconductor layer structure; and
a metal gate runner on the semiconductor layer structure that comprises an inner gate runner that comprises a first inner segment and a second inner segment that interconnect at a first oblique angle.

2. The semiconductor device of claim 1, wherein the first inner segment extends from the gate pad along an axis that defines a second oblique angle with respect to a first major side of the gate pad.

3. The semiconductor device of claim 2, wherein the first inner segment connects the gate pad to the second inner segment.

4. (canceled)

5. The semiconductor device of claim 2, further comprising a plurality of source bond pads, wherein the first inner segment is positioned between a first of the source bond pads and a second of the source bond pads.

6. The semiconductor device of claim 5, wherein the semiconductor device comprises a metal oxide semiconductor field effect transistor that comprises a plurality of unit cell transistors, and wherein a straight current path is provided between each unit cell transistor and at least one of source bond pads.

7. (canceled)

8. The semiconductor device of claim 1, wherein the second inner segment extends in parallel to a first major side of the semiconductor layer structure, and the first inner segment extends from the second inner segment toward a corner region of the semiconductor layer structure.

9. The semiconductor device of claim 1, wherein the inner gate runner further comprises a third inner segment, and the first inner segment, the second inner segment and the third inner segment each extend in different directions.

10. The semiconductor device of claim 9, wherein the inner gate runner further comprises a fourth inner segment, and the first inner segment, the second inner segment, the third inner segment and the fourth inner segment each extend in different directions.

11. The semiconductor device of claim 1, wherein the semiconductor layer structure comprises an active region, and wherein the metal gate runner further comprises an outer gate runner that extends around a portion of a periphery of the active region, where the outer gate runner comprises a first outer segment.

12. The semiconductor device of claim 11, wherein the inner first inner segment extends from the first outer segment.

13. The semiconductor device of claim 11, wherein the outer gate runner further comprises a second outer segment, and the first inner segment is interposed an on electrical path between the first outer segment and the second outer segment.

14-25. (canceled)

26. A semiconductor device, comprising:
a semiconductor layer structure;
a gate pad on the semiconductor layer structure; and
a metal gate runner that comprises an inner gate runner that comprises a first inner segment that extends in a first direction, a second inner segment that extends in a second direction and a third inner segment that extends in a third direction, where the first direction, the second direction and the third direction are different.

27. (canceled)

28. The semiconductor device of claim 26, wherein the first inner segment extends from the gate pad along an axis that defines a first oblique angle with respect to a first major side of the gate pad.

29. The semiconductor device of claim 28, wherein the first inner segment extends from a corner region of the gate pad.

30-31. (canceled)

32. The semiconductor device of claim 26, wherein the first inner segment is electrically interposed between the gate pad and the second inner segment, and the second inner segment is electrically interposed between the first inner segment and the third inner segment, and the third inner segment interconnects to the second inner segment at a second oblique angle.

33-37. (canceled)

38. The semiconductor device of claim 26, wherein the first inner segment extends from the gate pad along a first axis that defines a first oblique angle with respect to a first major side of the gate pad, and the second inner segment extends from the gate pad along a second axis that defines a second oblique angle with respect to the first major side of the gate pad.

39. A semiconductor device, comprising:
a semiconductor layer structure that comprises a plurality of major sides;
a gate pad on the semiconductor layer structure; and
a metal gate runner that comprises an inner gate runner that comprises a first inner segment that extends along an axis that defines an oblique angle with respect to a first of the major sides of the semiconductor layer structure.

40. The semiconductor device of claim 39, wherein the first inner segment directly connects to the gate pad.

41. The semiconductor device of claim 40, wherein the gate pad comprises first and second major sides that extend along perpendicular axes and the first inner segment extends from a corner region of the gate pad at an angle of between 30° and 60° with respect to the first major side of the gate pad.

42-43. (canceled)

44. The semiconductor device of claim 39, wherein the inner gate runner further comprises a second inner segment and a third inner segment, and wherein the first inner segment, the second inner segment and the third inner segment each extend in different directions.

45-62. (canceled)
